(19) United States
(12) Patent Application Publication
(10) Pub. No.: US 2018/0019858 A1
(43) Pub. Date: Jan. 18, 2018

(54) CIRCUIT FOR ENHANCING SENSITIVITY OF MOBILE DEVICE

(71) Applicant: MediaTek Singapore Pte. Ltd., Singapore (SG)

(72) Inventor: Weiwei PEI, Shenzhen City (CN)

(21) Appl. No.: 15/646,397

(22) Filed: Jul. 11, 2017

(30) Foreign Application Priority Data
Jul. 15, 2016 (CN) 201610565407.8

(51) Int. Cl. H04L 5/14; H03F 3/19; H04B 1/44; H04W 88/02

(52) U.S. Cl. CPC H04L 5/14; H04B 1/44; H03F 3/19; H03F 2200/294; H04W 88/02; H03F 2200/465

(57) ABSTRACT

A circuit for enhancing sensitivity of a mobile device is provided. The mobile device includes a transceiver and an antenna. The circuit is coupled between the transceiver and the antenna. The circuit includes a first terminal, a second terminal, a control terminal, a first switch circuitry, a second switch circuitry, and at least one low-noise amplifier. The first terminal is coupled to the transceiver. The second terminal is coupled to the antenna. The control terminal receives a control signal. When the antenna receives a signal, the circuit, according to the control signal, controls the first terminal coupled to the second terminal through the first switch circuitry, the low-noise amplifier, and the second switch circuitry. Through the above circuit, the sensitivity of the antenna is enhanced, the performance of the antenna is improved, and user experience is improved.

### CROSS REFERENCE TO RELATED APPLICATIONS

This Application claims priority of China Patent Application No. 201610565407.8, filed on Jul. 15, 2016, the entirety of which is incorporated by reference herein.

### BACKGROUND OF THE INVENTION

### Field of the Invention

The invention generally relates to wireless communication techniques, and more particularly to mobile devices and circuits for enhancing the sensitivity of mobile devices.

### Description of the Related Art

Frequency bands used for communication by current mobile devices have increased in number. For example, there are more frequency bands for mobile phones. Thus, front-end materials have become more complicated, resulting in poor receiving performance of the RF modules of the mobile phones. The receiving performance of some mobile phones is close to the lower limitations of the 3GPP (3^{rd} Generation Partnership Project) standard.

Moreover, there is a long-term tendency toward metallizing and ultra-thinning mobile phones, which results in a degradation of antenna performance of the mobile phones, and therefore unsatisfactory user experience.

### BRIEF SUMMARY OF THE INVENTION

It is desired to provide mobile devices and circuits for enhancing the sensitivity of mobile devices to solve the above problems.

An exemplary embodiment of a circuit for enhancing sensitivity of a mobile device. The mobile device comprises a transceiver and an antenna. The circuit is coupled between the transceiver and the antenna. The circuit comprises a first terminal, a second terminal, a control terminal, a first switch circuitry, a second switch circuitry, and at least one low-noise amplifier. The first terminal is coupled to the transceiver. The second terminal is coupled to the antenna. The control terminal receives a control signal. When the antenna receives a signal, the circuit, according to the control signal, controls the first terminal coupled to the second terminal through the first switch circuitry, the at least one low-noise amplifier, and the second switch circuitry.

An exemplary embodiment of a mobile device is provided. The mobile device comprises a transceiver module, an antenna, and a circuit for enhancing sensitivity. The circuit is coupled between the transceiver module and the antenna. The circuit is the circuit which is described above.

According to the above embodiments, the circuit is coupled between the transceiver and the antenna. the circuit of each exemplary embodiment is coupled between the transceiver and the antenna. When the emitting power of the transceiver is greater than or equal to a predetermined power threshold, the circuit, according to the control signal, controls the first terminal to be coupled to the second terminal through the first switch circuitry. When the antenna receives signals, the circuit, according to the control signal, controls the first terminal to be coupled to the second terminal through the first switch circuitry, the low-noise amplifier and the second switch circuitry. Then, the transceiver receives the signals through the low-noise amplifier, which results in a lowered noise factor, better antenna sensitivity, better antenna performance, and an improved user experience.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a first exemplary embodiment of a circuit for enhancing sensitivity;

FIG. 2 shows a second exemplary embodiment of a circuit for enhancing sensitivity;

FIG. 3 shows an exemplary embodiment of a power detector;

FIG. 4 shows a fourth exemplary embodiment of a circuit for enhancing sensitivity; and

FIG. 5 shows an exemplary embodiment of a mobile device.

### DETAILED DESCRIPTION OF THE INVENTION

The following will describe technical solutions of the embodiments of this application in detail and clearly by referring the accompanying drawings. Obviously, the described embodiments are merely part of the embodiments of the present application, but not all embodiments. Based on the embodiments of the present application, all other embodiments, which are obtained by those of ordinary skill in the art when they do not make any creative work, should belong to the scope of protection of the present application.

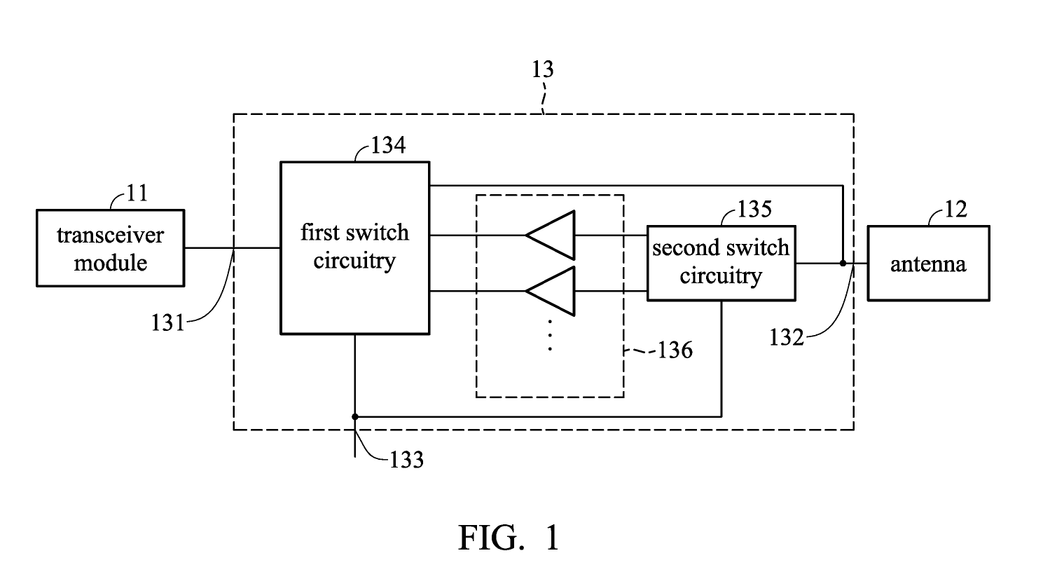

FIG. 1 shows a first exemplary embodiment of a circuit for enhancing sensitivity. The circuit disclosed in the embodiment can be applied in a mobile device such as a mobile phone, a palmtop computer, or a tablet computer. Preferably, the circuit is applied in a mobile phone operating under TDD (Time Division Duplexing) specification. The circuit can also be applied in a mobile phone operating under both TDD and FDD (Frequency Division Duplexing).

As shown in FIG. 1, the mobile device comprises a transceiver module 11 and an antenna 12. The circuit 13 is coupled between the transceiver module 11 and the antenna 12.

The circuit 13 comprises a first terminal 131, a second terminal 132, a control terminal 133, a first switch circuitry 134, a second switch circuitry 135, and at least one low-noise amplifier 136. The first terminal 131 of the circuit 13 is coupled to the transceiver module 11. The second terminal 132 of the circuit 13 is coupled to the antenna 12. The control terminal 133 of the circuit 13 is coupled to receive a control signal.

When the transmission power of the transceiver module 11 is equal to or greater than a predetermined power threshold, when the antenna 12 receives signals, the circuit 13, according to the control signal, controls the first terminal 131 to be coupled to the second terminal 132 through the first switch circuitry 134, the low-noise amplifier 136, and the second switch circuitry 135. That is, the transceiver module 11 is coupled to the antenna 12 through the first terminal 131, the first switch circuitry 134, the low-noise amplifier 136, the second switch circuitry 135, and the second terminal 132. At this time, the transceiver module 11 receives signals through the low-noise amplifier 136. Wherein the low-noise amplifier 136 is disposed before a filter. Thus, the noise coefficient is reduced, the sensitivity of the antenna 12 is enhanced, and the performance of the antenna 12 is upgraded, therefore the user experience is improved.

When the strength of the signal received by the antenna 12 is greater than a predetermined signal-strength threshold, the circuit 13, according to the control signal, controls the first terminal 131 to be coupled to the second terminal 132 through the first switch circuitry 134. That is, the transceiver module 11 is coupled to the antenna 12 through the first terminal 131, the first switch circuitry 134, and the second terminal 132. At this time, the transceiver module 11 does not need to receive any signal through the low-noise amplifier 136.

Moreover, when the module device needs to transmit signals through the antenna 12, the circuit 13, according to the control signal, the control circuit 13 controls the first terminal 131 to be coupled to the second terminal 132 through the first switch circuitry 134. Then, the mobile device transmits signals directly through the antenna 12.

In the embodiment, preferably, the gain of the low-noise amplifier 136 is 10-12 db. In one embodiment, when there are several low-noise amplifiers including at least one low-noise amplifier 136, the noise factor for the low-noise amplifiers coupled in parallel is less than 1.5 db.

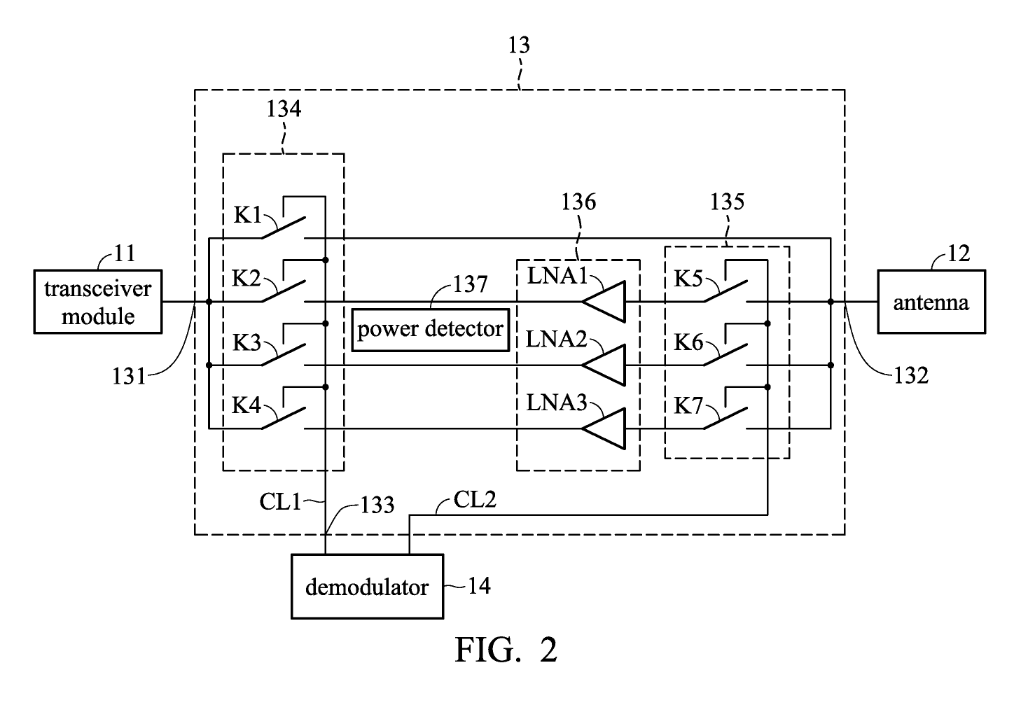

A second exemplary embodiment of a circuit for enhancing sensitivity is provided and will be described based on the circuit shown in the first exemplary embodiment. As shown in FIG. 2, there are a first low-noise amplifier LNA1, a second low-noise amplifier LNA2, and a third low-noise amplifier LNA3 for the implement of the at least one low-noise amplifier 136. The first low-noise amplifier LNA1 is applied for a first frequency band, the second low-noise amplifier LNA2 is applied for a second frequency band, and the third low-noise amplifier LNA3 is applied for a third frequency band.

The first switch circuitry 134 comprises a first switch K1, a second switch K2, a third switch K3, and a fourth switch K4. One terminal of the first switch K 1, one terminal of the second switch K2, one terminal of the third switch K3, one terminal of the fourth terminal K4 are all coupled to the first terminal 131 of the circuit 13. The other terminal of the first switch K1 is coupled to the second terminal 132 of the circuit 13, and the control terminal of the first switch K1 receives a first control signal CL1. The other terminal of the second switch K2 is coupled to the output terminal of the first low-noise amplifier LNA1, and the control terminal of the second switch K2 receives the first control signal CL1. The other terminal of the third switch K3 is coupled to the output terminal of the second low-noise amplifier LNA2, and the control terminal of the third switch K3 receives the first control signal CL1. The other terminal of the fourth switch K4 is coupled to the output terminal of the third low-noise amplifier LNA3, and the control terminal of the fourth switch K4 receives the first control signal CL1.

The second switch circuitry 135 comprises a fifth switch K5, a sixth switch K6, and a seventh switch K7. One terminal of the fifth switch K5, one terminal of the sixth switch K6, and one terminal of the seventh switch K7 are all coupled to the second terminal 132 of the circuit 13. The other terminal of the fifth switch K5 is coupled to the input terminal of the first low-noise amplifier LNA1, and the control terminal of the fifth switch K5 receives a second control signal CL2. The other terminal of the sixth switch K6 is coupled to the input terminal of the second low-noise amplifier LNA2, and the control terminal of the sixth switch K6 receives the second control signal CL2. The other terminal of the seventh switch K7 is coupled to the input terminal of the third low-noise amplifier LNA3, and the control terminal of the seventh switch K7 receives the second control signal CL2.

When the antenna 12 receives a signal which is in the first frequency band, the circuit 13 controls the second switch K2 to be turned on according to the first control signal CL1 and further controls the fifth switch K5 to be turned on according to the control signal CL2. Moreover, the circuit 13 also controls the first switch K1, the third switch K3, and the fourth switch K4 to be turned off according to the first control signal CL1, and the circuit 13 further controls the sixth switch K6 and the seventh switch K7 to be turned off according to the control signal CL2. Then, the transceiver module 11 is coupled to the antenna 12 through the first terminal 131, the second switch K2, the first low-noise amplifier LNA1, the fifth switch K5, and the second terminal 132. At this time, the transceiver module 11 receives the signal through the first low-noise amplifier LNA1. Preferably, the first frequency band is a frequency band at 1 GHz.

When the antenna 12 receives a signal which is in the second frequency band, the circuit 13 controls the third switch K3 to be turned on according to the first control signal CL1 and further controls the sixth switch K6 to be turned on according to the control signal CL2. Moreover, the circuit 13 also controls the first switch K1, the second switch K2, and the fourth switch K4 to be turned off according to the first control signal CL1, and the circuit 13 further controls the fifth switch K5 and the seventh switch K7 to be turned off according to the control signal CL2. Then, the transceiver module 11 is coupled to the antenna 12 through the first terminal 131, the third switch K3, the second low-noise amplifier LNA2, the sixth switch K6, and the second terminal 132. At this time, the transceiver module 11 receives the signal through the second low-noise amplifier LNA2. Preferably, the second frequency band is a frequency band from 1.8 GHz to 2.7 GHz.

When the antenna 12 receives a signal which is in the third frequency band, the circuit 13 controls the fourth switch K4 to be turned on according to the first control signal CL1 and further controls the seventh switch K7 to be turned on according to the control signal CL2. Moreover, the circuit 13 also controls the first switch K1, the second switch K2, and the third switch K3 to be turned off according to the first control signal CL1, and the circuit 13 further controls the fifth switch K5 and the sixth switch K6 to be turned off according to the control signal CL2. Then, the transceiver module 11 is coupled to the antenna 12 through the first terminal 131, the fourth switch K4, the third low-noise amplifier LNA3, the seventh switch K7, and the second terminal 132. At this time, the transceiver module 11 receives the signal through the third low-noise amplifier LNA3. Preferably, the third frequency band is a frequency band which is equal to or higher than 3.0 GHz.

When the antenna 12 receives a signal whose strength is greater than a predetermined signal-strength threshold, the circuit 13, according to the first control signal CL1, controls the first switch K1 to be turned on and controls the second switch K2, the third switch K3, and the fourth switch K4 to be turned off, and the circuit 13 further, according to the control signal CL2, controls the fifth switch K5, the sixth switch K6, and the seventh switch K7 to be turned off. Then, the transceiver module 11 is coupled to the antenna 12 through the first terminal 131, the first switch K1, and the second terminal 132. The first low-noise amplifier LNA1, the second low-noise amplifier LNA2, and the third low-noise amplifier LNA3 do not need to work, thereby saving power.

The mobile device further comprises a demodulator 14. The demodulator 14 is coupled to the circuit 13 through a serial bus interface or a parallel bus interface. The demodulator 14 is configured to provide the first control signal CL1 and the second control signal CL2 to the circuit 13. The demodulator 14 may further be configured to supply power to the circuit. Moreover, the demodulator 14 demodulates the signal received by the antenna 12; that is, the demodulator 14 recovers the low-frequency digital signal which has been modulated in the signal.

In cases where the mobile device is a mobile phone operating under FDD (Frequency Division Duplexing) specification, when the mobile phone receives and transmits signals, the circuit 13 controls the first switch K1, the second switch K2, the third switch K3, and the fourth switch K4 to be turned off according to the first control signal CL1, and the circuit 13 further controls the fifth switch K5, the sixth switch K6, and the seventh switch K7 to be turned off according to the second control signal CL2. The power capacity of the link where the first switch K1 is on is greater than 35 dbm, and the consumed power is less than 0.5 db, which decreases the disadvantageous effect on the mobile phone with the FDD specification.

The circuit 13 further comprises a power detector 137. The power detector 137 is coupled to the at least one low-noise amplifier 136 for detecting the power of the signal which is amplified by the low-noise amplifier 136. In another embodiment, the power detector 137 is coupled to each of the low-noise amplifiers.

Specifically, the power detector 137 is coupled to the output terminal of the at least one low-noise amplifier 136 to detect whether the output power of the low-noise amplifier 136 exceeds a predetermined power threshold. If the output power of the low-noise amplifier 136 exceeds the predetermined power threshold, the circuit 13, according to the first control signal CL1, controls the first switch K1 to be turned on and controls the second switch K2, the third switch K3, and the fourth switch K4 to be turned off, and the circuit 13 further, according to the control signal CL2, controls the fifth switch K5, the sixth switch K6, and the seventh switch K7 to be turned off.

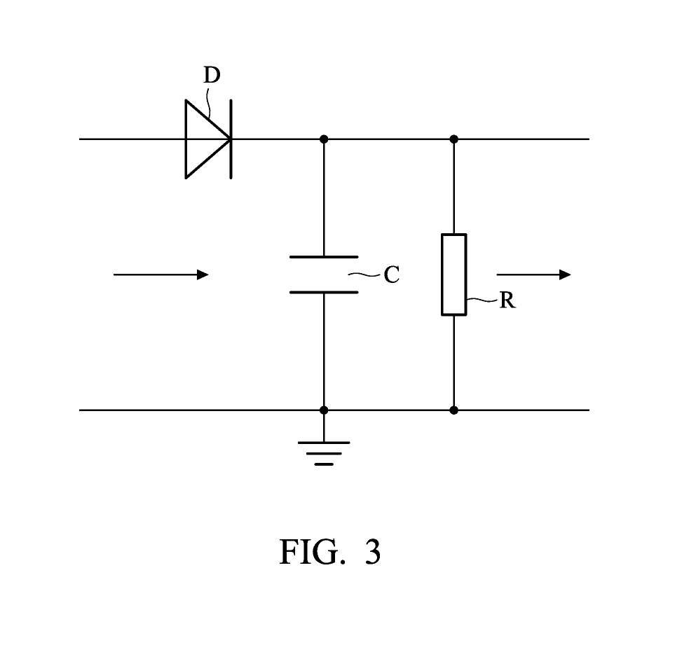

As shown in FIG. 3, the power detector 137 comprises a diode D, a capacitor C, and a resistor R. The anode of the diode D is inputted by a signal, and the cathode of the diode is coupled to one terminal of the capacitor C and one terminal of the resistor R. The other terminal of the capacitor C and the other terminal of the resistor R are coupled to the ground. The power detector 137 is coupled to detect the magnitude of the power. When the output power of the low-noise amplifier 136 is excessively high, the circuit 13 is blocked easily. However, according to the embodiment, in this case, the circuit 13 controls the first switch K1 to be turned on according to the first control signal CL1, which prevents blocking.

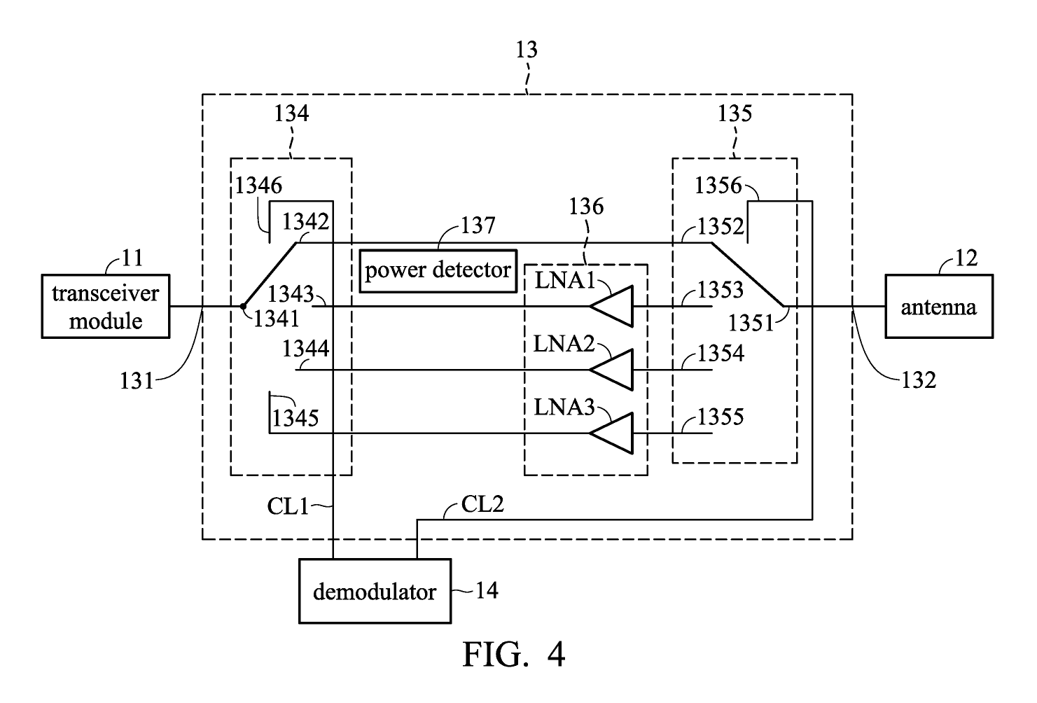

A third exemplary embodiment of a circuit for enhancing sensitivity is provided. The difference between the third exemplary embodiment and the second exemplary embodiment will be described in the following. As shown in FIG. 4, the first switch circuitry 134 is a single-pole-four-throw switch. The first terminal 1341 of the first switch circuitry 134 is coupled to the first terminal 131 of the circuit 13, the second terminal 1342 of the first switch circuitry 134 is coupled to second switch circuitry 135 of the circuit 13, the third terminal 1343 of the first switch circuitry 134 is coupled to the output terminal of the first low-noise amplifier LNA1, the fourth terminal 1344 of the first switch circuitry 134 is coupled to the output terminal of the second low-noise amplifier LNA2, the fifth terminal 1345 of the first switch circuitry 134 is coupled to the output terminal of the third low-noise amplifier LNA3, and the control terminal 1346 of the first switch circuitry 134 receives the first control signal CL1.

The second switch circuitry 135 is a single-pole-four-throw switch. The first terminal 1351 of the second switch circuitry 135 is coupled to the second terminal 132 of the circuit 13, the second terminal 1352 of the second switch circuitry 135 is coupled to the second terminal 1342 of the first switch circuitry 134, the third terminal 1353 of the second switch circuitry 135 is coupled to the input terminal of the first low-noise amplifier LNA1, the fourth terminal 1354 of the second switch circuitry 135 is coupled to the input terminal of the second low-noise amplifier LNA2, the fifth terminal 1355 of the second switch circuitry 135 is coupled to the input terminal of the third low-noise amplifier LNA3, and the control terminal 1356 of the second switch circuitry 135 receives the second control signal CL2.

When the antenna 12 receives a signal which is in the first frequency band, the circuit 13 controls the first terminal 1341 of the first switch circuitry 134 to be coupled to the third terminal 1343 according to the first control signal CL1 and further controls the first terminal 1351 of the second switch circuitry 135 to be coupled to the third terminal 1353 according to the second control signal CL2.

When the antenna 12 receives a signal which is in the second frequency band, the circuit 13 controls the first terminal 1341 of the first switch circuitry 134 to be coupled to the fourth terminal 1344 according to the first control signal CL1 and further controls the first terminal 1351 of the second switch circuitry 135 to be coupled to the fourth terminal 1354 according to the second control signal CL2.

When the antenna 12 receives a signal which is in the third frequency band, the circuit 13 controls the first terminal 1341 of the first switch circuitry 134 to be coupled to the fifth terminal 1345 according to the first control signal CL1 and further controls the first terminal 1351 of the second switch circuitry 135 to be coupled to the fifth terminal 1355 according to the second control signal CL2.

When the antenna 12 receives a signal whose strength is greater than a predetermined signal-strength threshold, the circuit 13 controls the first terminal 1341 of the first switch circuitry 134 to be coupled to the second terminal 1342 according to the first control signal CL1 and further controls the first terminal 1351 of the second switch circuitry 135 to be coupled to the second terminal 1352 according to the second control signal CL2.

In cases where the mobile device is operating under an FDD specification, when the mobile phone receives and emits signals, the circuit 13 controls the first terminal 1341 of the first switch circuitry 134 to be coupled to the second terminal 1342 according to the first control signal CL1 and further controls the first terminal 1351 of the second switch circuitry 135 to be coupled to the second terminal 1352 according to the second control signal CL2.

Compared with the circuit shown in the second exemplary embodiment, the circuit of the third exemplary embodiment can further reduce the cost.

The circuit 13 shown in each of the above embodiments can greatly enhance the sensitivity of the mobile device by about 3-5 db. The cost of each low-noise amplifier is about ¥0.7 (CNY). The cost of three the low-noise amplifiers is about ¥2 (CNY). The estimated cost of the circuit is therefore about ¥2 (CNY). Thus, the cost of the mobile device is not increased too much.

Moreover, a fourth exemplary embodiment of a circuit for enhancing sensitivity is provided. In this embodiment, the circuit 13 is integrated into the transceiver module 11. Compared with the circuit shown in the first exemplary embodiment, the cost of the circuit in the fourth exemplary embodiment is lower. Specifically, the estimated cost of the circuit is about ¥1.5 (CNY).

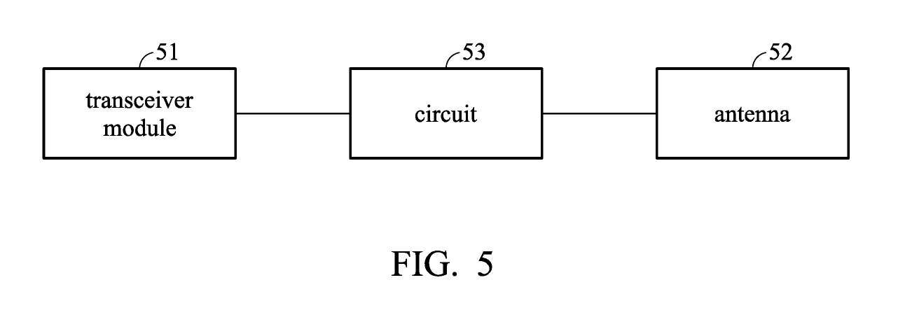

Another exemplary embodiment of a mobile device is provided. As shown in FIG. 5, the mobile device comprises a transceiver module 51, an antenna 52, and a circuit 53 for enhancing sensitivity. The circuit 53 is coupled between the transceiver module 51 and the antenna 52. Preferably, the circuit 53 is one of the circuits shown in the exemplary embodiments above. In the conventional art, which employs the LNA after the transceiver module, then more LNAs are needed and the sensitivity improvement of the receiving is very limited. The embodiments of this application apply LNA at the antenna port, before the transceiver module, the receiving performance can be greatly enhanced by 4-5 db.

As described above, the circuit of each exemplary embodiment is coupled between the transceiver and the antenna. When the transmission power of the transceiver is greater than or equal to a predetermined power threshold, the circuit, according to the control signal, controls the first terminal to be coupled to the second terminal through the first switch circuitry. When the antenna receives signals, the circuit, according to the control signal, controls the first terminal to be coupled to the second terminal through the first switch circuitry, the low-noise amplifier and the second switch circuitry. Then, the transceiver receives the signals through the low-noise amplifier, which results in a lower noise factor, better antenna sensitivity, better antenna performance, and an improved user experience.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit for enhancing sensitivity of a mobile device, the mobile device comprising a transceiver and an antenna, the circuit being coupled between the transceiver and the antenna, and the circuit comprising:
a first terminal coupled to the transceiver;
a second terminal coupled to the antenna;
a control terminal receiving a control signal;
a first switch circuitry;
a second switch circuitry; and
at least one low-noise amplifier,
wherein when the antenna receives a signal, the circuit, according to the control signal, controls the first terminal coupled to the second terminal through the first switch circuitry, the at least one low-noise amplifier, and the second switch circuitry.

2. The circuit for enhancing sensitivity as claimed in claim 1, wherein when strength of the signal is greater than a predetermined signal-strength threshold, the circuit, according to the control signal, controls the first terminal to be coupled to the second terminal through the first switch circuitry.

3. The circuit for enhancing sensitivity as claimed in claim 2,
wherein the at least one low-noise amplifier comprises a first low-noise amplifier, a second low-noise amplifier, and a third low-noise amplifier, and
wherein the first low-noise amplifier is applied for a first frequency band, the second low-noise amplifier is applied for a second frequency band, and the third low-noise amplifier is applied for a third frequency band.

4. The circuit for enhancing sensitivity as claimed in claim 3,
wherein the first switch circuitry comprises a first switch, a second switch, a third switch, and a fourth switch,
wherein one terminal of the first switch, one terminal of the second switch, one terminal of the third switch, one terminal of the fourth terminal are coupled to the first terminal of the circuit,
wherein another terminal of the first switch is coupled to the second terminal of the circuit, and a control terminal of the first switch receives a first control signal,
wherein another terminal of the second switch is coupled to an output terminal of the first low-noise amplifier, and a control terminal of the second switch receives the first control signal,
wherein another terminal of the third switch is coupled to an output terminal of the second low-noise amplifier, and a control terminal of the third switch receives the first control signal, and
wherein another terminal of the fourth switch is coupled to an output terminal of the third low-noise amplifier, and a control terminal of the fourth switch receives the first control signal.

5. The circuit for enhancing sensitivity as claimed in claim 4,
wherein the second switch circuitry comprises a fifth switch, a sixth switch, and a seventh switch,
wherein one terminal of the fifth switch, one terminal of the sixth switch, and one terminal of the seventh switch are coupled to the second terminal of the circuit,
wherein another terminal of the fifth switch is coupled to an input terminal of the first low-noise amplifier, and a control terminal of the fifth switch
wherein another terminal of the sixth switch is coupled to an input terminal of the second low-noise amplifier, and a control terminal of the sixth switch receives the second control signal, and
wherein another terminal of the seventh switch is coupled to an input terminal of the third low-noise amplifier, and a control terminal of the seventh switch receives the second control signal.

6. The circuit for enhancing sensitivity as claimed in claim 5,
wherein when the antenna receives a signal which is in the first frequency band, the circuit controls the second switch to be turned on according to the first control signal and controls the fifth switch to be turned on according to the control signal,
wherein when the antenna receives a signal which is in the second frequency band, the circuit controls the third switch to be turned on according to the first control signal and controls the sixth switch to be turned on according to the control signal,
wherein when the antenna receives a signal which is in the third frequency band, the circuit controls the fourth switch to be turned on according to the first control signal and controls the seventh switch to be turned on according to the control signal, and
wherein when the antenna receives a signal whose strength is greater than the predetermined signal-strength threshold, the circuit controls the first switch to be turned on according to the first control signal.

7. The circuit for enhancing sensitivity as claimed in claim 3,
wherein the first switch circuitry is a single-pole-four-throw switch, and
wherein a first terminal of the first switch circuitry is coupled to the first terminal of the circuit, a second terminal of the first switch circuitry is coupled to the second switch circuitry, a third terminal of the first switch circuitry is coupled to an output terminal of the first low-noise amplifier, the fourth terminal of the first switch circuitry is coupled to an output terminal of the second low-noise amplifier, a fifth terminal of the first switch circuitry is coupled to an output terminal of the third low-noise amplifier, and a control terminal of the first switch circuitry receives a first control signal.

8. The circuit for enhancing sensitivity as claimed in claim 7,
wherein the second switch circuitry is a single-pole-four-throw switch, and
wherein a first terminal of the second switch circuitry is coupled to the second terminal of the circuit, a second terminal of the second switch circuitry is coupled to the second terminal of the first switch circuitry, a third terminal of the second switch circuitry is coupled to an input terminal of the first low-noise amplifier, a fourth terminal of the second switch circuitry is coupled to an input terminal of the second low-noise amplifier, a fifth terminal of the second switch circuitry is coupled to an input terminal of the third low-noise amplifier, and a control terminal of the second switch circuitry receives a second control signal.

9. The circuit for enhancing sensitivity as claimed in claim 8,
wherein when the antenna receives a signal which is in the first frequency band, the circuit controls the first terminal of the first switch circuitry to be coupled to the third terminal of the first switch circuitry according to the first control signal and controls the first terminal of the second switch circuitry to be coupled to the third terminal of the second switch circuitry according to the second control signal,
wherein when the antenna receives a signal which is in the second frequency band, the circuit controls the first terminal of the first switch circuitry to be coupled to the fourth terminal of the first switch circuitry according to the first control signal and controls the first terminal of the second switch circuitry to be coupled to the fourth terminal of the second switch circuitry according to the second control signal;
wherein when the antenna receives a signal which is in the third frequency band, the circuit controls the first terminal of the first switch circuitry to be coupled to the fifth terminal of the first switch circuitry according to the first control signal and controls the first terminal of the second switch circuitry to be coupled to the fifth terminal of the second switch circuitry according to the second control signal, and
wherein when the antenna receives a signal whose strength is greater than the predetermined signal-strength threshold, the circuit controls the first terminal of the first switch circuitry to be coupled to the second terminal of the first switch circuitry according to the first control signal and controls the first terminal of the second switch circuitry to be coupled to the second terminal of the second switch circuitry according to the second control signal.

10. The circuit for enhancing sensitivity as claimed in claim 2 further comprising a power detector, coupled to the at least one low-noise amplifier, for detecting power of the signal which is processed by the at least one low-noise amplifier.

11. The circuit for enhancing sensitivity as claimed in claim 1, wherein the circuit is integrated into the transceiver module.

12. The circuit for enhancing sensitivity as claimed in claim 1, wherein the mobile device is operating under TDD specification.

13. The circuit for enhancing sensitivity as claimed in claim 1, wherein the mobile device is operating under TDD specification and FDD specification.

14. A mobile device comprising:
a transceiver module;
an antenna; and
a circuit, for enhancing sensitivity coupled between the transceiver module and the antenna, the circuit being coupled between the transceiver and the antenna, and the circuit comprising:
a first terminal coupled to the transceiver;
a second terminal coupled to the antenna;
a control terminal receiving a control signal;
a first switch circuitry;
a second switch circuitry; and
at least one low-noise amplifier,
wherein when the antenna receives a signal, the circuit, according to the control signal, controls the first terminal coupled to the second terminal through the first switch circuitry, the at least one low-noise amplifier, and the second switch circuitry.

15. The mobile device as claimed in claim 14, wherein when strength of the signal is greater than a predetermined signal-strength threshold, the circuit, according to the control signal, controls the first terminal to be coupled to the second terminal through the first switch circuitry.

16. The mobile device as claimed in claim 15,
wherein the at least one low-noise amplifier comprises a first low-noise amplifier, a second low-noise amplifier, and a third low-noise amplifier, and
wherein the first low-noise amplifier is applied for a first frequency band, the second low-noise amplifier is applied for a second frequency band, and the third low-noise amplifier is applied for a third frequency band.

17. The mobile device as claimed in claim 16,
wherein the first switch circuitry comprises a first switch, a second switch, a third switch, and a fourth switch,
wherein one terminal of the first switch, one terminal of the second switch, one terminal of the third switch, one terminal of the fourth terminal are coupled to the first terminal of the circuit,
wherein another terminal of the first switch is coupled to the second terminal of the circuit, and a control terminal of the first switch receives a first control signal,
wherein another terminal of the second switch is coupled to an output terminal of the first low-noise amplifier, and a control terminal of the second switch receives the first control signal,
wherein another terminal of the third switch is coupled to an output terminal of the second low-noise amplifier, and a control terminal of the third switch receives the first control signal, and
wherein another terminal of the fourth switch is coupled to an output terminal of the third low-noise amplifier, and a control terminal of the fourth switch receives the first control signal,

18. The mobile device as claimed in claim 16,
wherein the first switch circuitry is a single-pole-four-throw switch,
wherein a first terminal of the first switch circuitry is coupled to the first terminal of the circuit, a second terminal of the first switch circuitry is coupled to the second switch circuitry, a third terminal of the first switch circuitry is coupled to an output terminal of the first low-noise amplifier, the fourth terminal of the first switch circuitry is coupled to an output terminal of the second low-noise amplifier, a fifth terminal of the first switch circuitry is coupled to an output terminal of the third low-noise amplifier, and a control terminal of the first switch circuitry receives a first control signal.
wherein the second switch circuitry is a single-pole-four-throw switch, and
wherein a first terminal of the second switch circuitry is coupled to the second terminal of the circuit, a second terminal of the second switch circuitry is coupled to the second terminal of the first switch circuitry, a third terminal of the second switch circuitry is coupled to an input terminal of the first low-noise amplifier, a fourth terminal of the second switch circuitry is coupled to an input terminal of the second low-noise amplifier, a fifth terminal of the second switch circuitry is coupled to an input terminal of the third low-noise amplifier, and a control terminal of the second switch circuitry receives a second control signal.

19. The mobile device as claimed in claim 14, wherein the mobile device is operating under TDD specification.

20. The mobile device as claimed in claim 14, wherein the mobile device is operating under TDD specification and FDD specification.
